(19) United States
(12) Patent Application Publication
(10) Pub. No.: US 2011/0121917 A1
(43) Pub. Date: May 26, 2011

(54) MICROWAVE FILTER

(76) Inventor: Christine Blair, Queensland (AU)

(21) Appl. No.: 12/747,668

(22) PCT Filed: Dec. 15, 2008
(86) PCT No.: PCT/AU2008/001841

§ 371 Date: Dec. 16, 2010

(30) Foreign Application Priority Data
Dec. 13, 2007 (AU) 2007906787

(51) Int. Cl. H01P 1/205; H05K 13/00; B23K 31/02

(52) U.S. Cl. 333/203; 29/592.1; 228/164

(57) ABSTRACT

A filter filtering microwaves, the filter comprising a cavity and at least one metal comb-line resonator located within the cavity and at least one dielectric member surrounding the at least one metal comb-line resonator.

### FIELD OF THE INVENTION

This invention relates to a filter. In particular, the invention relates to a microwave filter for use in the telecommunications industry and therefore will be described in this context. However, it should be appreciated that the microwave filter may be used for other applications such as military, satellite, WIFI and television.

### BACKGROUND OF THE INVENTION

People throughout the world are demanding an increase in information to remote locations. This is achievable through the use of wireless telecommunication systems that are able to provide the necessary infrastructure to provide access to this information. One necessary component of wireless telecommunication base stations are microwave filters.

In any telecommunication base station, the amount of space available for equipment is limited. Accordingly, the dimensions of a microwave filter are an important consideration when designing a telecommunication base station. Unfortunately, due to the physics involved, the dimensions of the microwave filter is directly related to the frequencies being filtered. For example, in certain types of filter, the lower the frequency being filtered, the larger is the height required. With telecommunication towers filtering signals and frequencies in the range of 400 MHz to 4 GHz, the number and size of a microwave filter can vary considerably.

Further, with any microwave filter, there is the cost of manufacture which relates to both the materials used and the labour required. Even after a microwave filter has been assembled, it may require several hours of tuning.

### OBJECT OF THE INVENTION

It is an object of the invention to overcome or alleviate one or more of the above disadvantages or to provide the consumer with a more useful or commercial choice.

### SUMMARY OF THE INVENTION

In one form, although not necessarily the only or broadest form, the invention relates to a filter filtering microwaves, the filter comprising:

a cavity; and

at least one metal comb-line resonator located within the cavity; and

at least one dielectric member surrounding the at least one metal comb-line resonator.

Preferably, the filter includes a housing having a base and a lid.

Preferably, the resonator is located within the base. Preferably, the resonator is integrally formed with the base. However, the resonator may be detachable and may be formed from a different material, such as copper, to better control the frequency drift of the filter over a larger temperature range. The resonator may be screwed, soldered or fixed to the base using any process known in the art. The base is typically made from aluminum and coated with silver. However, it should be appreciated that any other materials may be used that would be evident to a person skilled in the art. For example, a gold coated plastic may be used.

The base may also include an inlet to allow microwaves to pass into the cavity in the housing and an outlet to allow microwaves to pass out of the cavity in the housing. A coupling element may form part of the inlet and/or outlet to connect the inlet and/or outlet to an adjacent resonator.

The dielectric member is preferably attached to the lid. The dielectric member may be soldered to the lid using a conductive material and the conductive material may be silver. The lid is preferably made from a material with a coefficient of thermal expansion well matched to that of the dielectric member to avoid the latter cracking with variation in ambient temperature.

Flux holes may be located within the lid to allow flux to pass through the lid during soldering to ensure a solid conductive metal connection between the lid and the dielectric member.

The dielectric member may be in the form of a hollow cylinder. Preferably, the dielectric member is made from a high Q ceramic material. The Q value of the dielectric member material should be in the range of 4000 to 35,000 at 1 GHz and preferably above 75,000 at 1 GHz. Additionally, the dielectric member material has a preferred dielectric constant in the range of 10 to 120.

The filter may further include at least one tuning screw for adjustment of coupling levels between various parts of the filter. Normally these coupling tuning screws are located in the lid of a filter. Preferably, the at least one coupling tuning screw is located between two resonators to control the coupling strength between the two resonators.

The filter may further include at least one frequency tuning screw. Normally the frequency tuning screw is located in the lid of the filter. However, persons skilled in that art may position the tuning screw in a different position. For example, the tuning screw may form part of the resonator. Preferably, the at least one frequency tuning screw is located within the dielectric material to vary the frequency of the resonator.

In another form, the invention resides in a method of manufacturing a filter, the method including the steps of:

locating at least one dielectric member over at least one metal comb-line resonator located within a cavity.

The method may further include one or more of the steps of:

forming at least one resonator within a cavity of a housing;

soldering at least one dielectric member onto a lid; and

placing tuning screws within a lid.

### BRIEF DESCRIPTION OF THE DRAWINGS

An embodiment of the invention, by way of example only, will now be described with reference to the accompanying figure in which:

FIG. 1 is a perspective view of a filter according to an embodiment of the invention; and

FIG. 2 is a further perspective view of a filter according to an embodiment of the invention.

### DETAILED DESCRIPTION OF THE PREFERRED EMBODIMENT

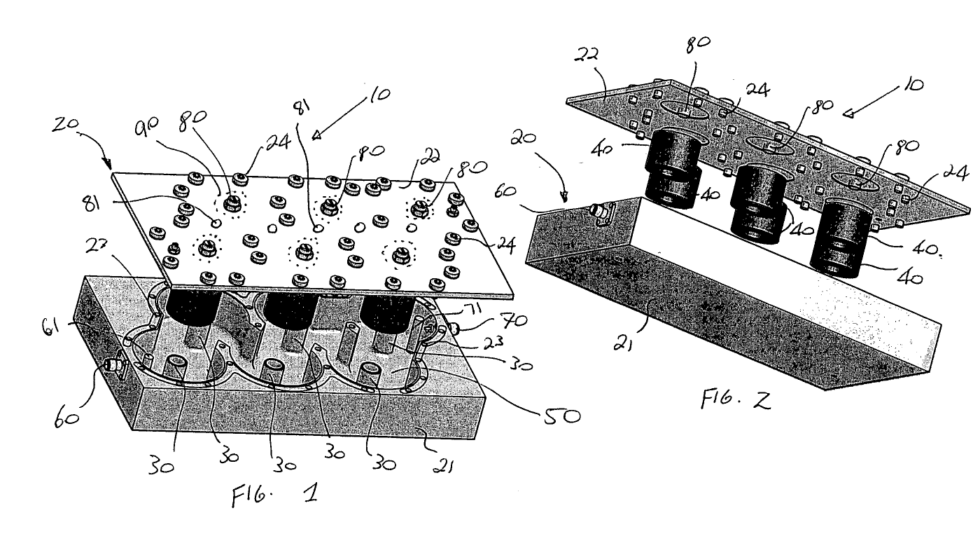

FIGS. 1 and 2 show a perspective view of a filter 10 for filtering microwaves. The filter 10 includes a housing 20, a series of resonators 30 and a series of dielectric members 40.

The housing 20 is manufactured from aluminum and has a base 21 and a lid 22. The base 21 includes a cavity 50 with a series of resonators 30 extending upwardly within the cavity 50. The resonators 30 and the base 21 are integrally molded. An inlet 60 is located at one side of the cavity 50 whilst an outlet 70 is located at an opposite end of the cavity 50. An inlet coupling element 61 forms part of the inlet whilst an outlet coupling element 71 forms part of the outlet 70. A series of fastening holes 23 are located are located through the base 21.

The lid 22 is a flat plate and has a series of fastening holes to hold the lid 22 to the base 21. Appropriate fasteners 24, such as screws, are located through the lid 22 and the base 21 to hold the lid 22 and the base 21 together. Dielectric members 40 are soldered to the lid 22 using a silver solder. Each dielectric member 40 is of a hollow cylindrical shape. The dielectric material used to produce each dielectric member 40 has a dielectric constant of 35. This material also has a Q of 35000 at 1 GHz. It should be appreciated that other suitable materials with different Qs may be utilized as would be recognised by a person skilled in the art.

Frequency tuning screws 80 are located through the lid 22 and within each dielectric member 40. The tuning screws 80 are of a standard format as will be recognised by a person skilled in the art. Coupling tuning screws 81 are also located through the lid 22 so that when the lid 22 is placed on the base 21, the coupling tuning screws 81 are located between adjacent resonators 30.

When the lid 22 is attached to the base 21, each dielectric member 40 is located over a respective resonator 30. Accordingly, each tuning screw 80 is also located adjacent a top of a respective resonator 30 and each coupling tuning screw 81 is between adjacent resonators 30. The height of the cavity 50 is greater than the height of each dielectric member 40. Therefore, when the lid 22 is placed on the base 21, an expansion gap is left between the dielectric members 40 and the base 21. Further, an expansion gap exists between each dielectric member 40 and the respective resonator 30.

In order to complete manufacture of the filter 10 the base 21 and lid 22 must be produced. The base 21 starts as a block of aluminum that is machined to form resonators 30 and an associated cavity 50. As the base 21 is made from aluminum, it is very quick and easy and hence cost effective machine the base 21. Once the base 21 is machined, a silver coating is placed over the base 21. It should be appreciated that the base 21 may be formed by other means than machining. For example, the base 21 may be made from plastic and injection molded. An inlet hole and outlet hole are then drilled through the base 21. The inlet 60 with associated coupling element 61 and outlet 70 with associated coupling element 71 are inserted to complete the base 21. Fastening holes are then drilled through the base 21 adjacent to the cavity 50. It should be appreciated that the sequence of steps to produce the base may be varied as would be evident to a person skilled in the art.

The lid 22 starts as a flat sheet of stainless steel 410. Stainless steel 410 is used to match the dielectric members 40 coefficient of thermal expansion so that the dielectric members 40 expand at the same rate during variations in temperature and the ceramic does not crack. Alternatively the lid 22 can be made out of a Printed Circuit Board (PCB) material, such as FR4, with a copper conductor plating to match the coefficient of thermal expansion of the lid 22 to the dielectric members 40. The lid 22 however can be made of any suitable material. In this case, the coefficient of thermal expansion of the stainless steel 410 material is 9.5 ppm/° C. and the coefficient of thermal expansion for the dielectric member 50 is 10 ppm/° C. Fastening holes, frequency tuning screw holes, coupling tuning screw holes and flux holes are drilled through the top of the lid 22. The whole lid 22 or masked areas of the lid 22 are then plated with silver to further improve the conductivity of the cavity 50.

In order to attach the dielectric members 40 to the lid 22, the lid 22 is heated to an appropriate temperature for soldering. Flux is located on the lid 22 adjacent to the flux holes 90. That is, at locations on which silver solder and the dielectric members 40 will be placed on the lid 22. Silver solder and the dielectric members 40 are then placed on the lid 22 to attach the lid 22 to the dielectric members 40. Any excess flux located between the lid 22 and the dielectric members 40 is forced through the flux holes so that the flux does not interfere with the bonding of the dielectric members 40 to the lid 22 by the silver solder. All soldering of all of the dielectric members 40 are contacted at one time. Minimum heating output is required as the lid 22 is a single sheet of stainless steel.

Once the lid 22 has cooled, coupling tuning screws 81, frequency tuning screw 80 and fastening screws 24 are located within respective holes in the lid 22.

Once the base 21 and lid 22 have been completed, the lid 22 is placed on the base 21 so that the dielectric members 40 are located over the resonators 30. The fastening screws 24 are screwed into the fastening holes 27 located within the base 21 to hold the lid 22 and the base 21 firmly together. At this point, the frequency tuning screws 80 are located adjacent respective resonators 30 and the coupling tuning screws 81 are located between adjacent resonators 30.

The final step to complete the manufacture of the filter 10 is to tune the filter 10. This is completed by adjusting the coupling tuning screws 81 to achieve the desired bandwidth and to adjust the frequency tuning screws 80 to achieve the desired frequency.

In use, the filter 10 is placed in a system in which microwaves are fed through the inlet 60. The microwaves pass through the cavity 50 where their frequency is changed to a desired frequency, e.g. 900 MHz. The microwaves then pass through the cavity 50, to the outlet 70 which is in turn connected to a receiver or transmitter.

It should be appreciated that depending on the required output frequency, the number of resonators 30 and the size of the cavity 50 may be increased or decreased as would be clear to a person skilled in the art. For example, there may be as little as a single resonator or as many as fifty resonators.

The above filter 10 provides many benefits including quick and easy tuning of the filter; quick, easy and inexpensive manufacture of the filter; low insertion loses and the ability to operate in TEM₀₁ mode. Further, the filter has a larger power handling capacity compared to a conventional comb-line resonator.

Furthermore the filter 10 described was designed for use in the GSM 900 band (935-960 MHz) and the Q value was 4000. If the dielectric member is removed, the resonant frequency of the resonators 30 increases to 2400 MHz. Alternatively, if the resonator 30 geometry is modified in order to operate in the GSM 900 band without the dielectric members 40, the power handling would be much reduced and the Q value would be reduced by 25%.

It will be appreciated that various other changes and modifications may be made to the embodiment described without departing from the spirit and scope of the invention.

1. A filter for filtering microwaves, the filter comprising:
a cavity; and
at least one metal comb-line resonator located within the cavity; and
at least one dielectric member surrounding the at least one metal comb-line resonator.

2. The filter of claim 1 wherein the filter includes a housing having a base and a lid, the resonator being located within the base.

3. The filter of claim 1 or claim 2 wherein the resonator is integrally formed with the base.

4. The filter of claim 2 wherein base includes an inlet to allow microwaves to pass into the cavity in the housing and an outlet to allow microwaves to pass out of the cavity in the housing.

5. The filter of any one of claims 2 to 4 wherein a coupling element forms part of the inlet and/or outlet to connect the inlet and/or outlet to an adjacent resonator.

6. The filter of any one of claims 2 to 5 wherein the dielectric member is attached to the lid.

7. The filter of any one of claims 2 to 6 wherein the dielectric member is soldered to the lid using a conductive material.

8. The filter of any one of claims 2 to 7 wherein the lid is made from a material with a coefficient of thermal expansion similar to that of the dielectric member.

9. The filter of any one of claims 2 to 8 wherein flux holes are located within the lid.

10. The filter of any one of the claims wherein the dielectric member is in the form of a hollow cylinder.

11. The filter of any one of the preceding claims wherein the filter further includes at least one coupling tuning screw is located between two resonators to control the coupling strength between the two resonators.

12. The filter of any one of the preceding claims wherein the filter further includes at least one frequency tuning screw located within the dielectric material to vary the frequency of the resonator.

13. A method of manufacturing a filter, the method including the steps of:
locating at least one dielectric member over at least one metal comb-line resonator located within a cavity.

14. The method of claim 13 further including the step of forming at least one resonator within a cavity of a housing.

15. The method of claim 13 or 14 further including the step of soldering at least one dielectric member onto a lid of a housing.

16. The method of claim 13, 14 or 15 further including the step of placing tuning screws within a lid of a housing.
